(19) United States
(12) Patent Application Publication
(10) Pub. No.: US 2026/0215247 A1
(43) Pub. Date: Jul. 23, 2026

(54) SEMICONDUCTOR DEVICE AND METHOD FOR MANUFACTURING THE SAME

(71) Applicant: TAIWAN SEMICONDUCTOR MANUFACTURING COMPANY LTD., HSINCHU (TW)

(72) Inventors: CHIN-SHEN LIN, TAIPEI CITY (TW); JIA-HONG GAO, HSINCHU COUNTY (TW); YUNG-FONG LU, HSINCHU CITY (TW)

(21) Appl. No.: 19/032,150

(22) Filed: Jan. 20, 2025

(51) Int. Cl. H01L 23/528; H01L 23/522

(52) U.S. Cl. CPC H10W 20/427; H10W 20/42; H10W 20/43; H10W 20/435

(57) ABSTRACT

A semiconductor device and a method for manufacturing the semiconductor device are provided. The semiconductor device includes a first back metal structure, a second back metal structure and an active region. The first back metal structure is formed on the back side of the wafer and extends in a first direction. The first back metal structure is configured in a fishbone structure including a first trunk portion and a plurality of first branch portions. The second back metal structure is formed on the back side of the wafer and extends in the first direction. The second back metal structure is spaced apart from the first back metal structure along a second direction vertical to the first direction from a top view. The second back metal structure is configured in the fishbone structure including a second trunk portion and a plurality of second branch portions.

### BACKGROUND

The present disclosure relates, in general, to semiconductor devices and methods for manufacturing the same. Specifically, the present disclosure relates to semiconductor devices and methods for manufacturing semiconductor devices with a header cell for power delivery.

Integrated circuits that involve semiconductor devices are essential for many modern applications. Technological advances in materials and design have produced semiconductor devices composed of smaller and more complex elements each generation. Although power consumption per element is reduced by miniaturization and reductions in voltage of elements, power consumption of the entire integrated circuit is rising due to increase in the number of elements. Therefore, a novel design of a header cell as a power switch cell is needed to reduce the turn-on resistance and improve the performance and stability.

### BRIEF DESCRIPTION OF THE DRAWINGS

Aspects of the embodiments of the present disclosure are best understood from the following detailed description when read with the accompanying figures. It should be noted that, in accordance with standard practice in the industry, various structures are not drawn to scale. In fact, the dimensions of the various structures can be arbitrarily increased or reduced for clarity of discussion.

FIG. 1A is a schematic view of a semiconductor device on a wafer, in accordance with some embodiments of the present disclosure.

FIG. 1B is a schematic view of a design layout of another semiconductor device, in accordance with some embodiments of the present disclosure.

FIG. 2 is a schematic diagram of a design layout of a semiconductor device, in accordance with some embodiments of the present disclosure.

FIG. 3A is a schematic diagram of a design layout of a semiconductor device, in accordance with some embodiments of the present disclosure.

FIG. 3B is a schematic diagram of a fishbone structure used for a semiconductor device, in accordance with some embodiments of the present disclosure.

FIG. 3C is another schematic diagram of a fishbone structure used for a semiconductor device, in accordance with some embodiments of the present disclosure.

FIG. 3D illustrates cross-section views of a semiconductor device along the section line C3 in FIG. 3A, in accordance with some embodiments of the present disclosure.

FIG. 4 is a schematic diagram of a design layout of a semiconductor device, in accordance with some embodiments of the present disclosure.

FIG. 5 is another schematic diagram of a design layout of a semiconductor device, in accordance with some embodiments of the present disclosure.

FIG. 6 is another schematic diagram of a design layout of a semiconductor device, in accordance with some embodiments of the present disclosure.

FIG. 7 is a flowchart of manufacturing a semiconductor device on a wafer with super power rails, in accordance with some embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features can be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, can be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus can be otherwise oriented (rotated 90 degrees or at other orientations) and the spatially relative descriptors used herein may likewise be interpreted accordingly.

As used herein, although terms such as “first,” “second” and “third” describe various elements, components, regions, layers and/or sections, these elements, components, regions, layers and/or sections should not be limited by these terms. These terms may only be used to distinguish one element, component, region, layer or section from another. Terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” and “about” generally mean within a value or range that can be contemplated by people having ordinary skill in the art. Alternatively, the terms “substantially,” “approximately” and “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

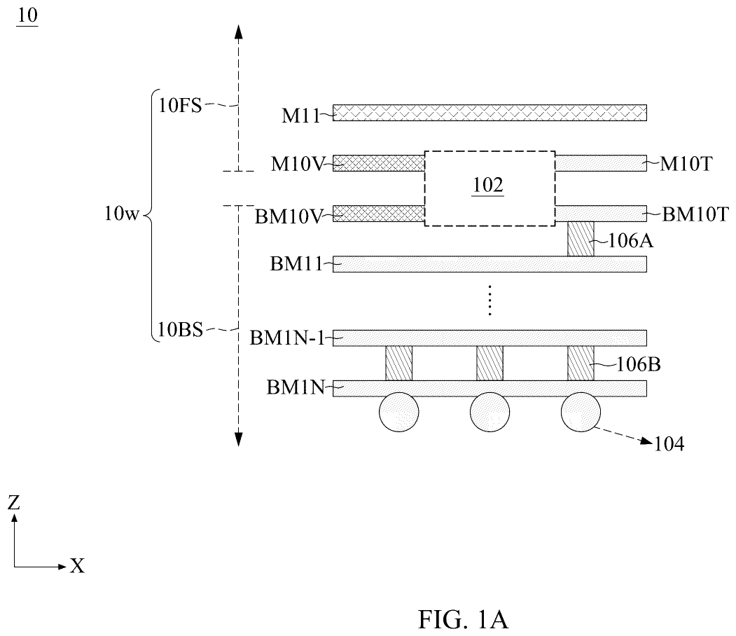

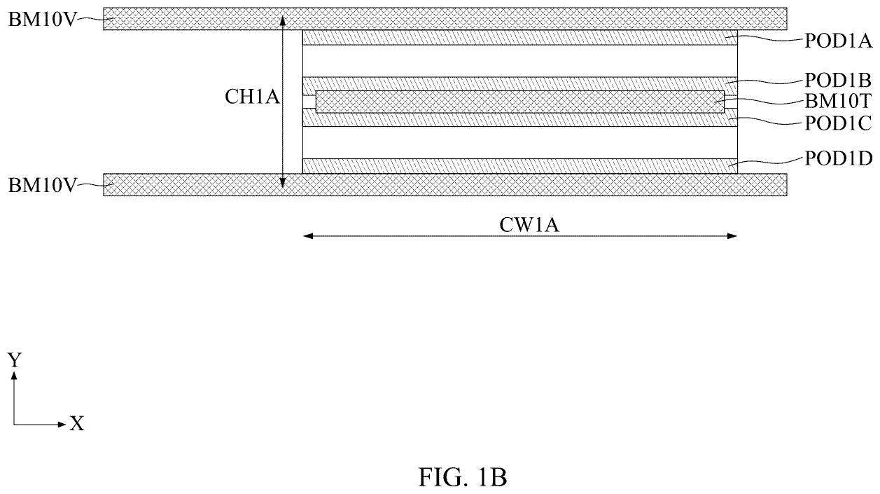

FIG. 1A is a schematic view of a semiconductor device 10 on a wafer 10w, in accordance with some embodiments of the present disclosure. The semiconductor device 10 can include, for example, an N-type metal-oxide-semiconductor (NMOS) device, a P-type metal-oxide-semiconductor (PMOS) device, and a complementary metal-oxide-semiconductor (CMOS) device, and can be implemented using a planar field-effect transistor (FET) device, a fin-type FET (FinFET) device, a gate-all-around (GAA) device, a nanowire device, a fully-depleted silicon-on-isolator (FDSOI) device, or the like. The wafer 10w includes a semiconductor substrate and, optionally, various layers formed thereon.

Referring to FIG. 1A, the semiconductor device 10 includes a header cell 102, multiple conductive contacts 104 for receiving power supplies and multiple metal structures M11 to BM1N, each extending along the X direction substantially parallel with each other. The header cell 102 spans the front side 10FS and the back side 10BS of the wafer 10w. The front side 10FS is opposite to the back side 10BS. The conductive contacts 104 can be electrically connected to a power source for providing power to the semiconductor device 10. In FIG. 1, the header cell 102 is represented by an empty dotted-box, without content therein. The details of the header cell 102 will be discussed later in accordance with FIG. 1B.

The metal structures M11 and M10, the latter of which includes two metal structures M10V and M10T, are formed on the front side 10FS of the wafer 10w. The metal structure M11 is formed above the header cell 102 and the metal structures M10V and M10T from a cross-sectional view. The conductive contacts 104 and the metal structures BM10, BM11 to BM1N-1 and BM1N are formed on the back side 10BS of the wafer 10w. The metal structure BM10 includes two metal structures BM10V and BM10T separated by the header cell 102. The via structure 106A is formed between the metal structures BM10T and BM11 from the cross-sectional view. The via structures 106B are formed between the metal structures BM1N-1 and BM1N from the cross-sectional view. The via structures 106A and 106B extend along the Z direction vertical to the X direction.

The header cell 102 can include a power switch cell to control power delivery of the semiconductor device 10. The technique of power gating may reduce power leakage when a system is not actively operating. The header cell 102 may provide a positive supply voltage VDD to other functional cells or elements of the semiconductor device 10, such as inverters, buffers, flip-flops and level shifters. The metal structures M11 to BM1N, the conductive contacts 104, and the via structures 106A and 106B are made of metal, such as copper, aluminum, tungsten, titanium, tantalum, an alloy thereof or the like, and are electrically insulated by dielectric materials (not separately shown) such as oxide, nitride, oxynitride and the like.

In some embodiments, the metal structures M10V and BM10V belong to a virtual power domain. The virtual power domain is configured to transmit power from the header cell 102 to a standard cell or a functional cell which includes various kinds of logic gates or electronic elements. In some embodiments, the metal structures M10T, BM10T, BM11 to BM1N-1 and BM1N belong to a true power domain. The true power domain is configured to transmit power from a power supply or a power source to the header cell 102. The semiconductor device 10 can belong to a super power rail (SPR) chip design which includes or provides a power delivery network through the front side 10FS and the back side 10BS of the wafer 10w.

FIG. 1B is a schematic view of a design layout of the semiconductor device 10A, in accordance with some embodiments of the present disclosure. The semiconductor device 10A of FIG. 1B can correspond to a top view of the header cell 102 of the semiconductor device 10 of FIG. 1A.

The semiconductor device 10A includes several metal structures BM10V and BM10T extending along the X direction. The semiconductor device 10A includes multiple active regions POD1A, POD1B, POD1C and POD1D extending along the X direction. The active regions POD1A to POD1D can include a P-type active region, also referred to herein as an oxide-diffusion (“OD”) region. The active region may be used to form source/drain regions and a channel region between the source/drain regions of a transistor device. The semiconductor device 10A includes multiple PMOS devices without NMOS devices to reduce turn-on resistance.

The metal structures BM10T can partially overlap with the active regions POD1B and POD1C from a top-view perspective of the design layout. The header cell height CH1A can be defined as the distance between the two metal structures BM10V. The header cell width CW1A can be defined as the length of the active regions POD1A to POD1D along the X direction. In some embodiments, the header cell height CH1A can be twice the standard cell height, which is determined as the distance between two successive active regions, such as the active regions POD1A and POD1B. The header cell width CW1A can be greater than the header cell height CH1A.

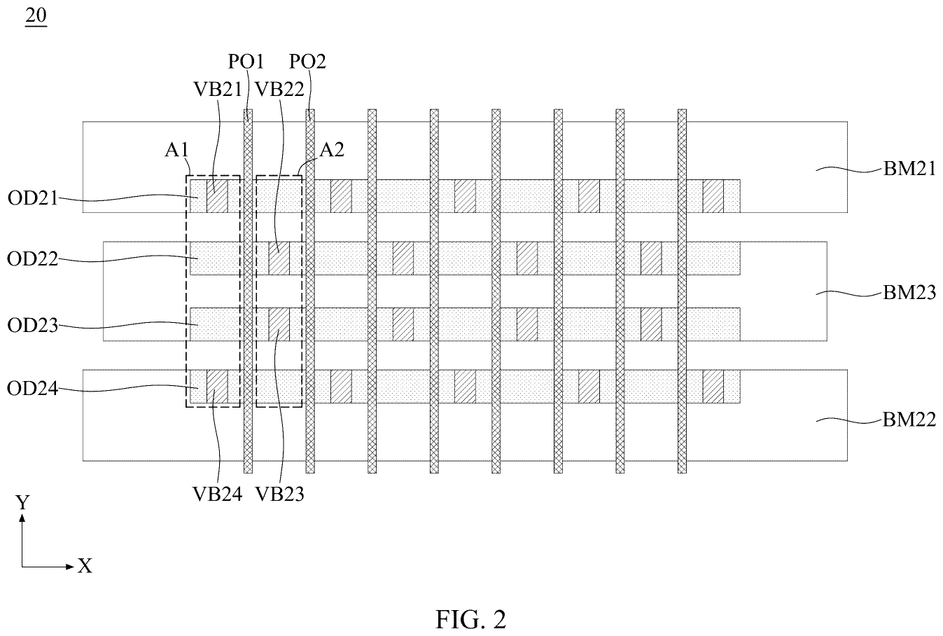

FIG. 2 is a schematic diagram of a design layout of a semiconductor device 20, in accordance with some embodiments of the present disclosure. The semiconductor device 20 of FIG. 2 can correspond to the header cell 102 as illustrated in the embodiments of FIG. 1A.

The semiconductor device 20 includes several back metal structures BM21, BM22 and BM23, several active regions OD21, OD22, OD23 and OD24, several gates PO1 and PO2, and several via structures VB21, VB22, VB23 and VB 24. The back metal structures BM21 to BM23, and the via structures VB21 to VB24 are made of metal, such as copper, aluminum, tungsten, titanium, tantalum, an alloy thereof or the like, and are electrically insulated by dielectric materials (not separately shown) such as oxide, nitride, oxynitride and the like.

The back metal structures BM21, BM22 and BM23 can be formed on the back side 10BS of the wafer 10w in FIG. 1A. The back metal structures BM21, BM22 and BM23 can extend along the X direction. The back metal structure BM23 is provided between the back metal structures BM21 and BM22 along the Y direction. The back metal structure BM23 can be spaced apart from the back metal structures BM21 and BM22 along the Y direction. In addition, the gates PO1 and PO2 can extend along the Y direction.

The active regions OD21, OD22, OD23 and OD24 can extend along the X direction. The active regions OD22 and OD23 are provided between the active regions OD21 and OD24 along the Y direction. In some embodiments, the active regions OD21, OD22, OD23 and OD24 can be formed above the back metal structures BM21, BM22 and BM23 from the cross-sectional view. The active region OD21 can overlap with the back metal structure BM21 from the top view. The active regions OD22 and OD23 can overlap with the back metal structure BM23 from the top view. The active region OD24 can overlap with the back metal structure BM22 from the top view.

As shown in FIG. 2, the via structure VB21 overlaps with the active region OD21 and the back metal structure BM21. The via structure VB22 overlaps with the active region OD22 and the back metal structure BM23. The via structure VB23 overlaps with the active region OD23 and the back metal structure BM23. The via structure VB24 overlaps with the active region OD24 and the back metal structure BM22. In some embodiments, the via structure VB21 can be formed between the active region OD21 and the back metal structure BM21 from the cross-sectional view. The via structure VB22 can be formed between the active region OD22 and the back metal structure BM23 from the cross-sectional view. The via structure VB23 can be formed between the active region OD23 and the back metal structure BM23 from the cross-sectional view. The via structure VB24 can be formed between the active region OD24 and the back metal structure BM22 from the cross-sectional view.

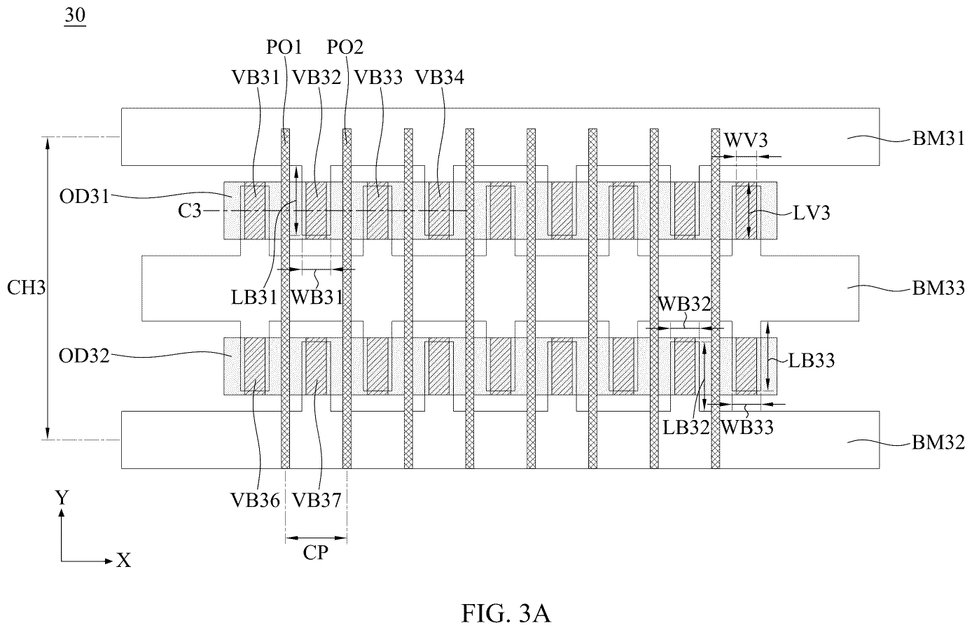

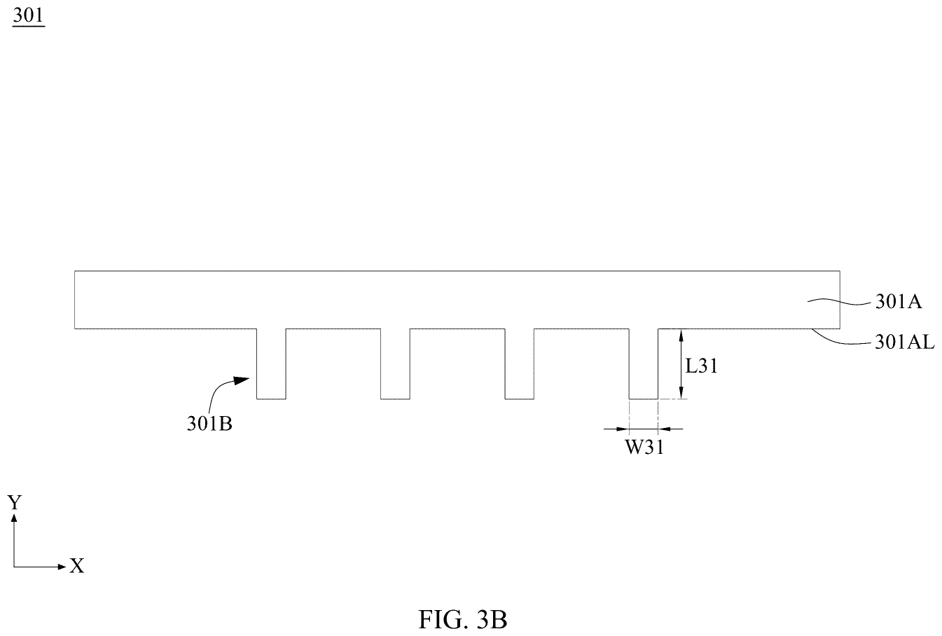

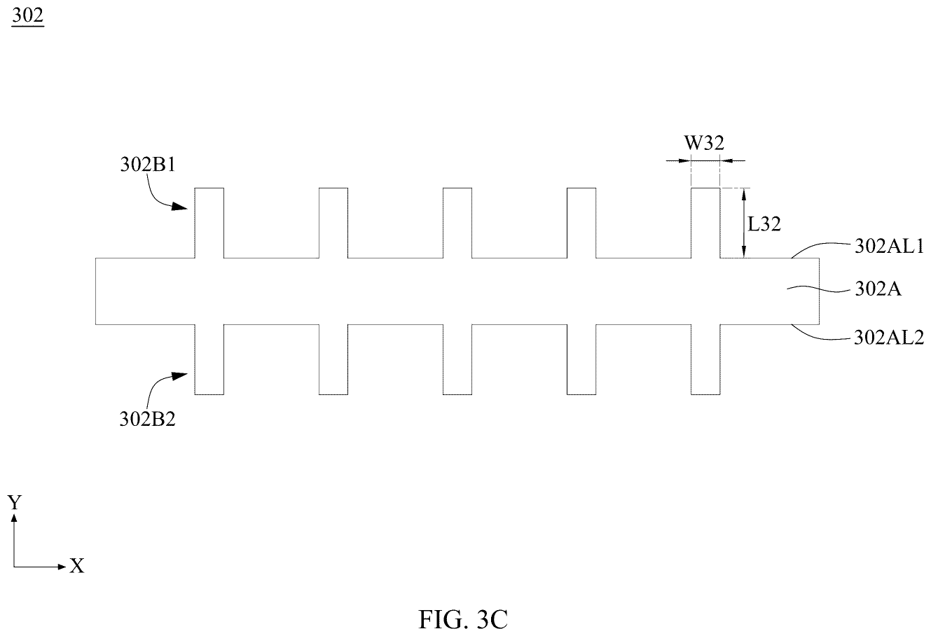

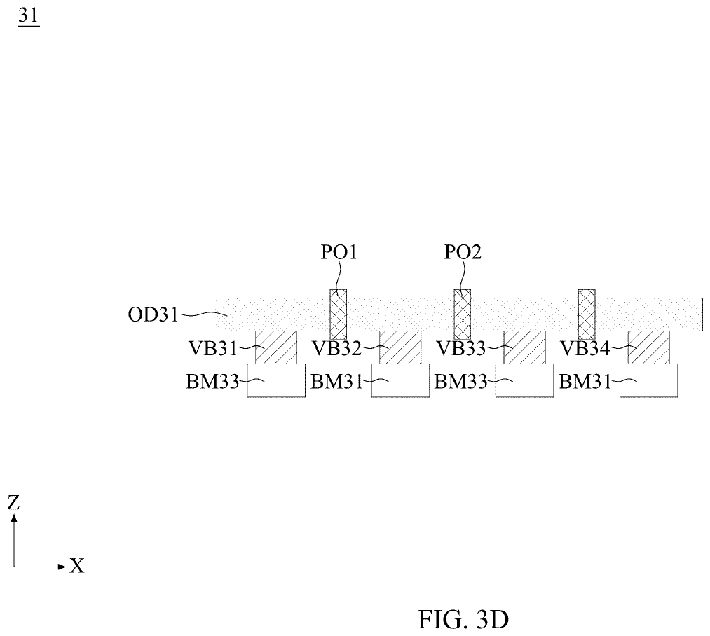

FIG. 3A is a schematic diagram of a design layout of a semiconductor device 30, in accordance with some embodiments of the present disclosure. The semiconductor device 30 of FIG. 3A can correspond to the header cell 102 as illustrated in the embodiments of FIG. 1A.

The semiconductor device 30 includes several back metal structures BM31, BM32 and BM33, two active regions OD31 and OD32, several gates PO1 and PO2, and several via structures VB31, VB32, VB33, VB34, VB36 and VB37. The back metal structures BM31, BM32 and BM33 can be formed on the back side 10BS of the wafer 10w in FIG. 1A. The back metal structures BM31, BM32 and BM33 can extend along the X direction. The back metal structure BM33 is provided between the back metal structures BM31 and BM32 along the Y direction. The back metal structure BM33 can be spaced apart from the back metal structures BM31 and BM32 along the Y direction. The back metal structure BM33 can belong to the true power domain for transmitting power from a power supply or a power source to the header cell. The back metal structures BM31 and BM32 can belong to the virtual power domain for transmitting power from the header cell to a standard cell or a functional cell. The active regions OD31 and OD32 can include a P-type active region, also referred to herein as an OD region. The active region may be used to form source/drain regions and a channel region between the source/drain regions of a transistor device.

FIG. 3B is a schematic diagram of a fishbone structure 301 used for a semiconductor device 30 of FIG. 3A, in accordance with some embodiments of the present disclosure. In some embodiments, the back metal structures BM31 and BM32 can be in the shape of the fishbone structure 301.

As shown in FIG. 3B, the fishbone structure 301 can include a trunk portion 301A and several branch portions 301B. The trunk portion 301A can extend along the X direction. The branch portions 301B can protrude from a lateral side 301AL of the trunk portion 301A. The branch portions 301B can extend along the Y direction. Each of the branch portions 301B can be parallel with each other. Each of the branch portions 301B can have different lengths along the Y direction. Each of the branch portions 301B can have substantially the same length L31 along the Y direction. Each of the branch portions 301B can have different widths along the X direction. Each of the branch portions 301B can have substantially the same width W31 along the X direction.

FIG. 3C is another schematic diagram of a fishbone structure 302 used for a semiconductor device 30 of FIG. 3A, in accordance with some embodiments of the present disclosure. In some embodiments, the back metal structure BM33 can be in the shape of the fishbone structure 302.

As shown in FIG. 3C, the fishbone structure 302 can include a trunk portion 302A and several branch portions 302B1 and 302B2. The trunk portion 302A can extend along the X direction. The trunk portion 302A has two opposite lateral sides 302AL1 and 302AL2. A set of the branch portions 302B1 can protrude from the lateral side 302AL1 of the trunk portion 302A, and another set of the branch portions 302B2 can protrude from the lateral side 302AL2 of the trunk portion 302A. The branch portions 302B1 and 302B2 can extend along the Y direction. The branch portions 302B1 and 302B2 can extend toward opposite directions. Each of the branch portions 302B1 and 302B2 can be parallel with each other. Each of the branch portions 302B1 and 302B2 can have different lengths along the Y direction. Each of the branch portions 302B1 and 302B2 can have substantially the same length L32 along the Y direction. Each of the branch portions 302B1 and 302B2 can have different widths along the X direction. Each of the branch portions 302B1 and 302B2 can have substantially the same width W32 along the X direction.

Referring back to the embodiments of FIG. 3A. The branch portions of the back metal structure BM31 can be staggered with the branch portions of the back metal structure BM33. In some embodiments, any two adjacent ones of the branch portions of the back metal structure BM31 can be separated by one of the branch portions of the back metal structure BM33 along the X direction. In some embodiments, any two adjacent ones of the branch portions of the back metal structure BM33 can be separated by one of the branch portions of the back metal structure BM31 along the X direction. In some embodiments, a gap between any two adjacent branch portions of the back metal structures BM31 and BM33 can have different values. In some embodiments, a gap between any two adjacent branch portions of the back metal structures BM31 and BM33 can have substantially the same value. The branch portions of the back metal structure BM31 can extend along the Y direction and face toward the back metal structure BM33.

The branch portions of the back metal structure BM32 can be staggered with the branch portions of the back metal structure BM33. In some embodiments, any two adjacent ones of the branch portions of the back metal structure BM32 can be separated by one of the branch portions of the back metal structure BM33 along the X direction. In some embodiments, any two adjacent ones of the branch portions of the back metal structure BM33 can be separated by one of the branch portions of the back metal structure BM32 along the X direction. In some embodiments, a gap between any two adjacent branch portions of the back metal structures BM32 and BM33 can have different values. In some embodiments, a gap between any two adjacent branch portions of the back metal structures BM32 and BM33 can have substantially the same value. The branch portions of the back metal structure BM32 can extend along the Y direction and face toward the back metal structure BM33.

As shown in FIG. 3A, the active region OD31 overlaps with the branch portions of the back metal structures BM31 and BM33 from the top view. The active region OD31 can partially cover the branch portions of the back metal structures BM31 and BM33. The active region OD31 can cover each of the front ends of the branch portions of the back metal structures BM31 and BM33. The active region OD31 can totally cover the branch portions of the back metal structures BM31 and BM33. The active region OD31 can be formed on the front side 10FS of the wafer 10w. The active region OD31 can extend along the X direction from the top view.

The active region OD31 can be parallel with and separated from the trunk portions of the back metal structures BM31 and BM33. The distance between the active region OD31 and the trunk portion of the back metal structures BM31 can be different from the distance between the active region OD31 and the trunk portion of the back metal structures BM33. The distance between the active region OD31 and the trunk portion of the back metal structures BM31 can be substantially identical to the distance between the active region OD31 and the trunk portion of the back metal structures BM33.

Each of the branch portions of the back metal structure BM31 can have a width WB31 and a length LB31. Each of the branch portions of the back metal structure BM33 can have a width WB33 and a length LB33. As shown in FIG. 3A, the pitch CP is defined as the distance between two successive gates PO1 and PO2. The cell height CH3 can be determined as the distance between two successive active regions BM31 and BM32 with the same power domain.

The widths WB31 and WB33 can be substantially the same. The widths WB31 and WB33 can be different. The lengths LB31 and LB33 can be substantially the same. The lengths LB31 and LB33 can be different. The lengths LB31 and LB33 can be greater than the widths WB31 and WB33. The cell height CH3 can be greater than the pitch CP. The cell height CH3 can be more than four times the pitch CP. In some embodiments, the widths WB31 and WB33 can be in a range of 0.1 CP to 10 CP. The lengths LB31 and LB33 can be in a range of 0.1 CH3 to 10CH3 .

In some embodiments, the active region OD32 overlaps with the branch portions of the back metal structures BM32 and BM33 from the top view. The active region OD32 can partially cover the branch portions of the back metal structures BM32 and BM33. The active region OD32 can cover each of the front ends of the branch portions of the back metal structures BM32 and BM33. The active region OD32 can totally cover the branch portions of the back metal structures BM32 and BM33. The active region OD32 can be formed on the front side 10FS of the wafer 10w. The active region OD32 can extend along the X direction from the top view.

The active region OD32 can be parallel with and separated from the trunk portions of the back metal structures BM32 and BM33. The distance between the active region OD32 and the trunk portion of the back metal structures BM32 can be different from the distance between the active region OD32 and the trunk portion of the back metal structures BM33. The distance between the active region OD32 and the trunk portion of the back metal structures BM32 can be substantially identical to the distance between the active region OD32 and the trunk portion of the back metal structures BM33.

Each of the branch portions of the back metal structure BM32 can have a width WB32 and a length LB32. The widths WB32 and WB33 can be substantially the same. The widths WB32 and WB33 can be different. The lengths LB32 and LB33 can be substantially the same. The lengths LB32 and LB33 can be different. The lengths LB32 and LB33 can be greater than the widths WB32 and WB33. In some embodiments, the widths WB32 and WB33 can be in a range of 0.1 CP to 10 CP. The lengths LB32 and LB33 can be in a range of 0.1 CH3 to 10CH3 .

Furthermore, the via structures VB31, VB32, VB33 and VB34 can partially overlap with the active region OD31. The via structures VB31, VB32, VB33 and VB34 can totally overlap with the active region OD31. The via structures VB31 and VB33 can overlap with the branch portions of the back metal structure BM33. The via structures VB31 and VB33 can be provided between the active region OD31 and the back metal structure BM33. The via structures VB32 and VB34 can overlap with the branch portions of the back metal structure BM31. The via structures VB32 and VB34 can be provided between the active region OD31 and the back metal structure BM31.

The via structures VB36 and VB37 can partially overlap with the active region OD32. The via structures VB36 and VB37 can totally overlap with the active region OD32. The via structure VB36 can overlap with the branch portions of the back metal structure BM33. The via structure VB36 can be provided between the active region OD32 and the back metal structure BM33. The via structure VB37 can overlap with the branch portions of the back metal structure BM32. The via structure VB37 can be provided between the active region OD32 and the back metal structure BM32.

The via structures VB31, VB32, VB33, VB34, VB36 and VB37 can have different sizes. The via structures VB31, VB32, VB33, VB34, VB36 and VB37 can have substantially the same size. Each of the via structures VB31, VB32, VB33, VB34, VB36 and VB37 can have a width WV3 and a length LV3. The width WV3 can be different from the widths WB31, WB32 and WB33. The width WV3 can be smaller than the widths WB31, WB32 and WB33. The length LV3 can be different from the lengths LB31, LB32 and LB33. The length LV3 can be smaller than the lengths LB31, LB32 and LB33.

FIG. 3D illustrates a cross-section view of the semiconductor device 31 along the section lines C3 in FIG. 3A, in accordance with some embodiments of the present disclosure. The semiconductor device 31 of FIG. 3D can correspond to the semiconductor device 30 of FIG. 3A.

The via structures VB31, VB32, VB33 and VB34 can be disposed above the back metal structures BM33 and BM31 along the Z direction. The active region OD31 can be disposed above the via structures VB31, VB32, VB33 and VB34 along the Z direction. The gates PO1 and PO2 can intersect with the active region OD31 and extend along the Y direction vertical to the X direction and Z direction. The gate PO1 can be formed between the via structures VB31 and VB32. The gate PO2 can be formed between the via structures VB32 and VB33.

In the embodiment of the semiconductor device 20 in FIG. 2, the back metal structures BM21 and BM22 can be electrically connected to the active regions OD21 and OD24 through the via structures VB21 and VB24 in the virtual power domain area A1. The back metal structure BM23 in the virtual power domain area A1 cannot be electrically connected to the active regions OD21 and OD24 directly, and they can be electrically connected to the active regions OD21 and OD24 through the signal routing and wiring on the front side. Accordingly, a high turn-on resistance can be created due to the long signal routing, and the performance and stability of the semiconductor device 20 may be deteriorated. Similarly, in the true power domain area A2, the back metal structures BM21 and BM22 cannot be electrically connected to the active regions OD22 and OD23 directly, and they can be electrically connected to the active regions OD22 and OD23 through the signal routing and wiring on the front side, which may increase the turn-on resistance of the semiconductor device 20.

In the embodiments of FIG. 3, by utilizing the two-dimensional fishbone structures, each of the back metal structures BM31 to BM33 can be electrically connected to both of the active regions OD31 and OD32 directly through the staggered branch portions and the corresponding via structures VB31 to VB37. The signal routing and wiring on the front side are not needed for the electrical connection to the active regions OD31 and OD32. Therefore, the turn-on resistance can be reduced to improve the performance and stability of the semiconductor device 30.

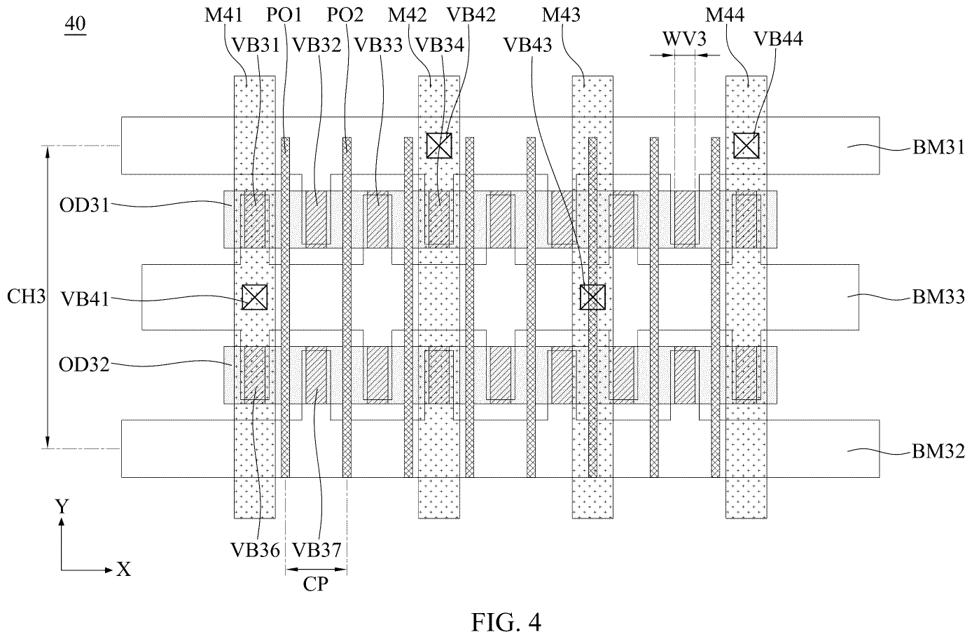

FIG. 4 is a schematic diagram of a design layout of a semiconductor device 40, in accordance with some embodiments of the present disclosure. The semiconductor device 40 of FIG. 4 can be similar to the semiconductor device 30 of FIG. 3A, except for the differences described as follows.

The semiconductor device 40 includes metal structures M41, M42, M43 and M44 extending along the Y direction. The metal structures M41, M42, M43 and M44 can be formed on the front side 10FS of the wafer 10w. The metal structures M41, M42, M43 and M44 can be in direct contact with the active regions OD31 and OD32. The metal structure M41 can be electrically connected to the back metal structure BM33 through the via structure VB41. The metal structure M42 can be electrically connected to the back metal structure BM31 through the via structure VB42. The metal structure M43 can be electrically connected to the back metal structure BM33 through the via structure VB43. The metal structure M44 can be electrically connected to the back metal structure BM31 through the via structure VB44. The metal structures M41, M42, M43 and M44 can have material similar to that of the back metal structures BM31 to BM32.

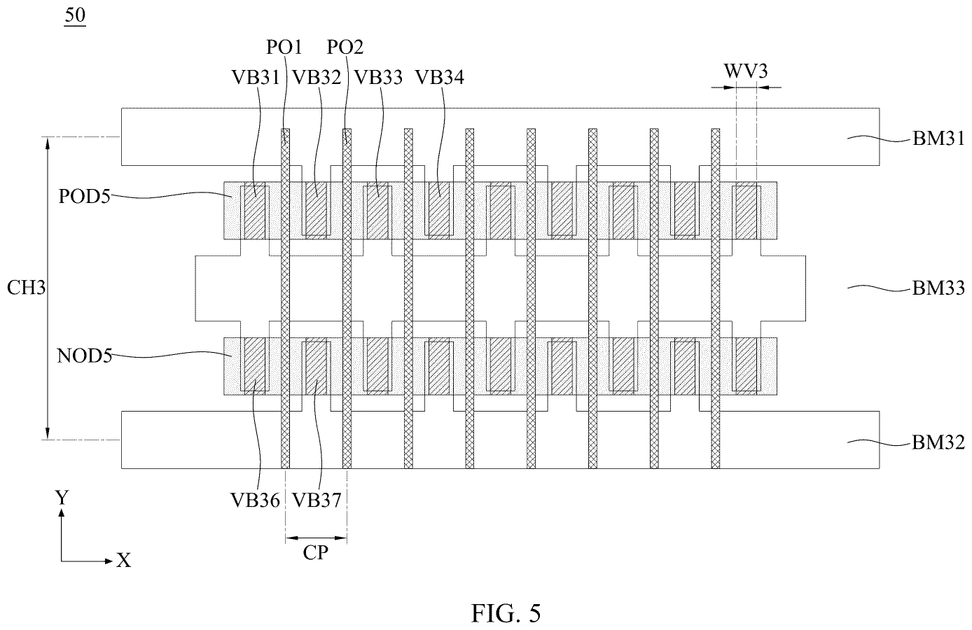

FIG. 5 is another schematic diagram of a design layout of a semiconductor device 50, in accordance with some embodiments of the present disclosure. The semiconductor device 50 of FIG. 5 can be similar to the semiconductor device 30 of FIG. 3A, except for the differences described as follows.

The semiconductor device 50 can be used for functional cells, such as inverters, buffers, flip-flops and level shifters. The back metal structure BM31 can be electrically connected to a voltage source VDD, and the back metal structure BM32 can be electrically connected to a voltage source VSS. The voltage supplied by the voltage source VDD can be greater than the voltage supplied by the voltage source VSS. The back metal structure BM33 can be electrically connected to an output pin of the functional cell. The active region POD5 can be P-type, and the active region NOD5 can be N-type.

By utilizing the two-dimensional fishbone structures for the functional cells, each of the back metal structures BM31 to BM33 can be electrically connected to both of the active regions POD5 and NOD5 directly through the staggered branch portions and the corresponding via structures VB31 to VB37. The signal routing and wiring on the front side are not needed for the electrical connection to the active regions POD5 and NOD5. Therefore, the turn-on resistance can be reduced to improve the performance and stability of the semiconductor device 50 for the functional cells.

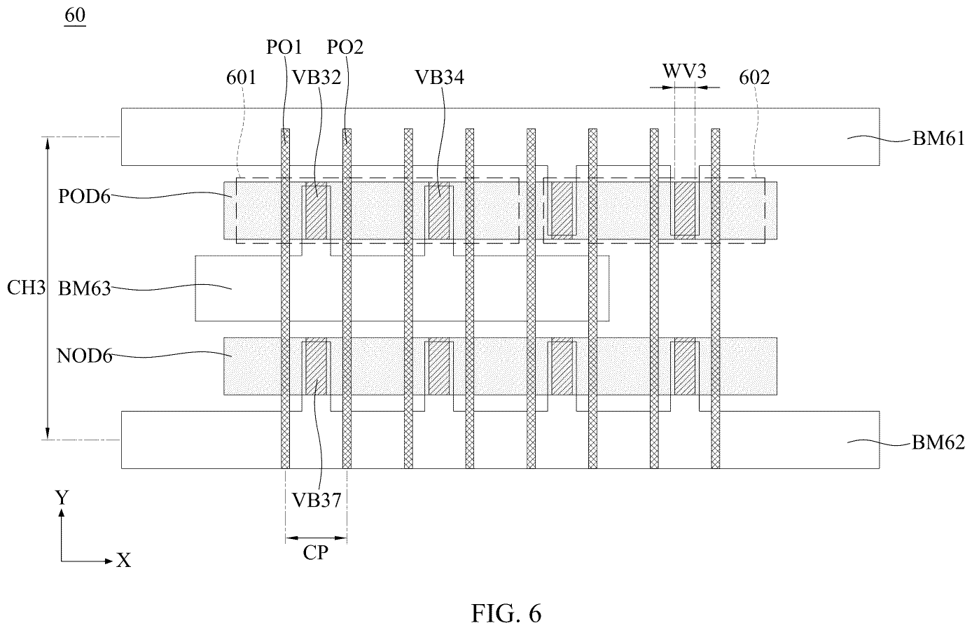

FIG. 6 is another schematic diagram of a design layout of a semiconductor device 60, in accordance with some embodiments of the present disclosure. The semiconductor device 60 of FIG. 6 can be similar to the semiconductor device 30 of FIG. 3A, except for the differences described as follows.

The semiconductor device 60 can be used for specific functional cells, such as always-on inverters, buffers, flip-flops and level shifters to perform limited functions while the whole system is in a sleep state. The back metal structure BM61 can be electrically connected to a voltage source VDD1. The back metal structure BM63 can be electrically connected to another voltage source VDD2 different from the voltage source VDD1. The back metal structure BM62 can be electrically connected to the voltage source VSS. The active region POD6 can be P-type, and the active region NOD6 can be N-type. In some embodiments, the length of the back metal structure BM63 can be smaller than that of the active regions POD6 and NOD6. In some embodiments, the length of the active regions POD6 and NOD6 can be smaller than that of the back metal structures BM61 and BM62.

In some embodiments, the voltage sources VDD1 and VDD2 can belong to the same power domain. In some embodiments, the voltage sources VDD1 and VDD2 can belong to different power domains. The voltage source VDD1 can belong to the true power domain, and the voltage source VDD2 can belong to the virtual power domain. The voltage source VDD2 can belong to the true power domain, and the voltage source VDD1 can belong to the virtual power domain. The voltages supplied by the voltage sources VDD1 and VDD2 can be greater than the voltage supplied by the voltage source VSS.

By utilizing the two-dimensional fishbone structures for the always-on applications, each of the back metal structures BM61 to BM63 can be electrically connected to both of the active regions POD6 and NOD6 directly through the staggered branch portions and the corresponding via structures VB31 to VB37. The signal routing and wiring on the front side are not needed for the electrical connection to the active regions POD6 and NOD6. Therefore, the turn-on resistance can be reduced to improve the performance and stability of the semiconductor device 60 for the always-on applications.

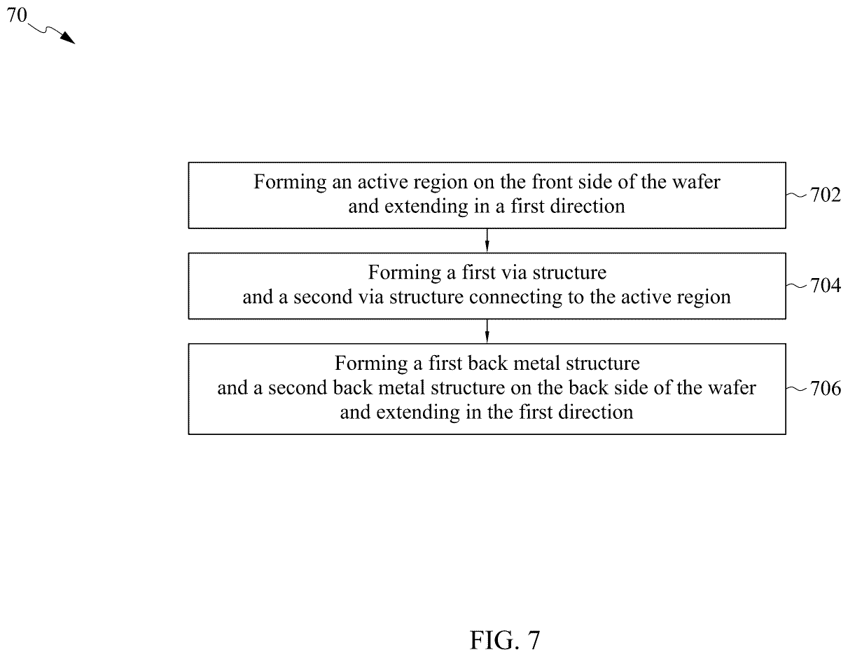

FIG. 7 is a flowchart of manufacturing a semiconductor device on a wafer with super power rails, in accordance with some embodiments of the present disclosure. The flowchart 70 can correspond to a process for manufacturing the semiconductor device 30 of FIG. 3A.

In the operation 702, an active region is formed on the front side of the wafer. The active region extends in the first direction. In the operation 704, a first via structure and a second via structure are formed connecting to the active region. In the operation 706, a first back metal structure and a second back metal structure are formed on the back side of the wafer. The first back metal structure extends in the first direction. The first back metal structure is configured in a fishbone structure comprising a first trunk portion and a plurality of first branch portions. The second back metal structure extends in the first direction. The second back metal structure is spaced apart from the first back metal structure along a second direction vertical to the first direction from a top view. The second back metal structure is configured in the fishbone structure comprising a second trunk portion and a plurality of second branch portions.

In some embodiments, the active region is between the first back metal structure and the second back metal structure from the top view, and above the first back metal structure and the second back metal structure from a cross-sectional view. The first branch portions and the second branch portions extend along the second direction, and the active region overlaps the first branch portions and the second branch portions. In some embodiments, the first via structure is formed between the active region and the first branch portions from the cross-sectional view. In some embodiments, the second via structure is formed between the active region and the second branch portions from the cross-sectional view.

While disclosed methods (e.g., flowchart 70) are illustrated and described below as a series of acts or events, it will be appreciated that the illustrated ordering of such acts or events are not to be interpreted in a limiting sense. For example, some operations may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

Some embodiments of the present disclosure provide a semiconductor device formed on a wafer having a front side and a back side. The semiconductor device includes a first back metal structure, a second back metal structure and an active region. The first back metal structure is formed on the back side of the wafer and extends in a first direction. The first back metal structure is configured in a fishbone structure including a first trunk portion and a plurality of first branch portions. The second back metal structure is formed on the back side of the wafer and extends in the first direction. The second back metal structure is spaced apart from the first back metal structure along a second direction vertical to the first direction from a top view. The second back metal structure is configured in the fishbone structure including a second trunk portion and a plurality of second branch portions. The second back metal structure belongs to a first power domain and the first back metal structure belongs to a second power domain different from the first power domain. The active region is formed on the front side of the wafer, extending in the first direction, formed between the first back metal structure and the second back metal structure from the top view.

Some embodiments of the present disclosure provide a semiconductor device formed on a wafer. The semiconductor device includes a first back metal structure, a second back metal structure, a third back metal structure, a first active region, and a second active region. The first back metal structure is formed on the back side of the wafer and extends in a first direction. The first back metal structure is configured in a fishbone structure including a first trunk portion and a plurality of first branch portions. The second back metal structure is formed on the back side of the wafer and extends in the first direction. The second back metal structure is spaced apart from the first back metal structure along a second direction vertical to the first direction from a top view. The second back metal structure is configured in the fishbone structure including a second trunk portion and a plurality of second branch portions. The third back metal structure is formed on the back side of the wafer and extends in the first direction. The third back metal structure is formed between the first back metal structure and the second back metal structure along the second direction from the top view. The third back metal structure is configured in the fishbone structure including a third trunk portion and a plurality of third branch portions. The first active region is formed on the front side of the wafer, extending in the first direction, formed between the first back metal structure and the third back metal structure from the top view, and formed above the first back metal structure and the third back metal structure from a cross-sectional view. The second active region is formed on the front side of the wafer, extending in the first direction, formed between the second back metal structure and the third back metal structure from the top view, and formed above the second back metal structure and the third back metal structure from the cross-sectional view.

Some embodiments of the present disclosure provide a method for manufacturing a semiconductor device. The method includes forming an active region on the front side of the wafer and extending in a first direction; forming a first via structure and a second via structure connecting to the active region; forming a first back metal structure and a second back metal structure on the back side of the wafer and extending in the first direction, wherein the first back metal structure is configured in a fishbone structure comprising a first trunk portion and a plurality of first branch portions; and forming a second back metal structure on the back side of the wafer and extending in the first direction, wherein the second back metal structure is spaced apart from the first back metal structure along a second direction vertical to the first direction from a top view, the second back metal structure is configured in the fishbone structure comprising a second trunk portion and a plurality of second branch portions, wherein the active region is between the first back metal structure and the second back metal structure from the top view, and above the first back metal structure and the second back metal structure from a cross-sectional view, wherein the first branch portions and the second branch portions extend along the second direction, and the active region overlaps the first branch portions and the second branch portions.

The foregoing outlines structures of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device formed on a wafer having a front side and a back side, comprising:
a first back metal structure formed on the back side of the wafer and extending in a first direction, wherein the first back metal structure is configured in a fishbone structure comprising a first trunk portion and a plurality of first branch portions;
a second back metal structure formed on the back side of the wafer and extending in the first direction, wherein the second back metal structure is spaced apart from the first back metal structure along a second direction vertical to the first direction from a top view, wherein the second back metal structure is configured in the fishbone structure comprising a second trunk portion and a plurality of second branch portions, and wherein the second back metal structure belongs to a first power domain and the first back metal structure belongs to a second power domain different from the first power domain; and
an active region formed on the front side of the wafer, extending in the first direction, formed between the first back metal structure and the second back metal structure from the top view.

2. The semiconductor device of claim 1, wherein the first power domain is configured to transmit power from a power supply to a switch cell, the second power domain is configured to transmit power from the switch cell to a standard cell, and the second power domain can be cut off by the switch cell.

3. The semiconductor device of claim 1, wherein the first branch portions are staggered with the second branch portions.

4. The semiconductor device of claim 1, wherein the active region is spaced apart from the first trunk portion and the second trunk portion.

5. The semiconductor device of claim 1, wherein the active region is formed above the first back metal structure and the second back metal structure from a cross-sectional view, and the first branch portions and the second branch portions extend along the second direction, and the active region overlaps the first branch portions and the second branch portions.

6. The semiconductor device of claim 5, further comprising:
a first via structure, formed between the active region and the first branch portions from the cross-sectional view; and
a second via structure, formed between the active region and the second branch portions from the cross-sectional view.

7. The semiconductor device of claim 6, wherein the active region partially covers the first branch portions and the second branch portions, and totally covers the first via structure and the second via structure.

8. The semiconductor device of claim 6, wherein a width of the first branch portions along the first direction is substantially identical to that of the second branch portions from the top view, and a length of the first branch portions along the second direction is substantially identical to that of the second branch portions from the top view.

9. The semiconductor device of claim 8, wherein the width of the first branch portions and the second branch portions is greater than the widths of the first via structure and the second via structure along the first direction from the top view.

10. A semiconductor device formed on a wafer having a front side and a back side, comprising:
a first back metal structure formed on the back side of the wafer and extending in a first direction, wherein the first back metal structure is configured in a fishbone structure comprising a first trunk portion and a plurality of first branch portions;
a second back metal structure formed on the back side of the wafer and extending in the first direction, wherein the second back metal structure is spaced apart from the first back metal structure along a second direction vertical to the first direction from a top view, wherein the second back metal structure is configured in the fishbone structure comprising a second trunk portion and a plurality of second branch portions;
a third back metal structure formed on the back side of the wafer and extending in the first direction, wherein the third back metal structure is formed between the first back metal structure and the second back metal structure along the second direction from the top view, wherein the third back metal structure is configured in the fishbone structure comprising a third trunk portion and a plurality of third branch portions;
a first active region formed on the front side of the wafer, extending in the first direction, formed between the first back metal structure and the third back metal structure from the top view, and formed above the first back metal structure and the third back metal structure from a cross-sectional view; and
a second active region formed on the front side of the wafer, extending in the first direction, formed between the second back metal structure and the third back metal structure from the top view, and formed above the second back metal structure and the third back metal structure from the cross-sectional view.

11. The semiconductor device of claim 10, wherein the first active region is P-type, and the second active region is N-type.

12. The semiconductor device of claim 10, wherein the first branch portions extend from a lateral side of the first trunk portion facing the first active region, the second branch portions extend from a lateral side of the second trunk portion facing the second active region, and the third branch portions extend from two opposite lateral sides of the third trunk portion facing the first active region and the second active region respectively.

13. The semiconductor device of claim 12, wherein the third branch portions are staggered with the first branch portions and the second branch portions.

14. The semiconductor device of claim 10, wherein the first branch portions and the third branch portions extend along the second direction, the first active region overlaps the first branch portions and the third branch portions from the top view, the second branch portions and the third branch portions extend along the second direction, and the second active region overlaps the second branch portions and the third branch portions from the top view.

15. The semiconductor device of claim 14, further comprising:
a first via structure, formed between the first active region and the first branch portions from the cross-sectional view;
a second via structure, formed between the first active region and the third branch portions from the cross-sectional view;
a third via structure, formed between the second active region and the third branch portions from the cross-sectional view; and
a fourth via structure, formed between the second active region and the second branch portions from the cross-sectional view.

16. The semiconductor device of claim 15, wherein the first active region partially covers the first branch portions and the third branch portions, and the second active region partially covers the second branch portions and the third branch portions.

17. The semiconductor device of claim 15, wherein the first active region totally covers the first via structure and the second via structure, and the second active region totally covers the third via structure and the fourth via structure.

18. A method for manufacturing a semiconductor device on a wafer having a front side and a back side, comprising:
forming an active region on the front side of the wafer and extending in a first direction;
forming a first via structure and a second via structure connecting to the active region; and
forming a first back metal structure and a second back metal structure on the back side of the wafer and extending in the first direction, wherein the first back metal structure is configured in a fishbone structure comprising a first trunk portion and a plurality of first branch portions, the second back metal structure is spaced apart from the first back metal structure along a second direction vertical to the first direction from a top view, the second back metal structure is configured in the fishbone structure comprising a second trunk portion and a plurality of second branch portions, wherein the active region is between the first back metal structure and the second back metal structure from the top view, and above the first back metal structure and the second back metal structure from a cross-sectional view, wherein the first branch portions and the second branch portions extend along the second direction, and the active region overlaps the first branch portions and the second branch portions.

19. The method of claim 18, wherein the first via structure is between the active region and the first branch portions from the cross-sectional view, and the second via structure is between the active region and the second branch portions from the cross-sectional view.

20. The method of claim 18, wherein the first branch portions are staggered with the second branch portions, and the active region partially covers the first branch portions and the second branch portions.
